(19) United States
(12) Patent Application Publication
(10) Pub. No.: US 2021/0195734 A1
(43) Pub. Date: Jun. 24, 2021

(54) Integrated circuit substrate having a recess for receiving a solder fillet

(71) Applicant: QDOS Flexcircuits Sdn Bhd, Bayan Lepas (MY)

(72) Inventors: Poh Cheng Ang, Bayan Lepas (MY); Chee Can Lee, Bayan Lepas (MY); Shin Hung Hwang, Bayan Lepas (MY)

(73) Assignee: QDOS Flexcircuits Sdn Bhd, Bayan Lepas (MY)

(21) Appl. No.: 17/119,687

(22) Filed: Dec. 11, 2020

(30) Foreign Application Priority Data
Dec. 23, 2019 (MY) PI 2019007698

(51) Int. Cl. H05K 1/02; H05K 1/09; H05K 3/12

(52) U.S. Cl. CPC H05K 1/0298; H05K 3/0097; H05K 3/12; H05K 1/09

(57) ABSTRACT

An integrated circuit substrate (100) including a conductive trace layer (102) formed by one or more conductive traces that are deposited on a partially or completely removable carrier (101), a stud conductive trace layer (103) formed by one or more stud traces that are disposed on at least one conductive trace of the conductive trace layer (102), in which each stacked conductive trace and stud trace forms an electronic conductive trace, and all electronic conductive traces positioned at the same level is defined as for forming an electronic conductive layer; a dielectric layer (104) occupying spaces within the stud conductive trace layer (103) and conductive trace layer (102), and at least one recess (105) formed at the electronic conductive trace of at least one electronic conductive layer, or between two electronic conductive traces of at least one electronic conductive layer, wherein each recess (105) exposes at least a portion of the conductive trace layer (102), stud conductive trace layer (103), dielectric layer (104) or any combination thereof.

### CROSS-REFERENCE TO RELATED APPLICATION

The instant application claims priority to Malaysia Patent Application Serial No. PI 2019007698 filed Dec. 23, 2019, the entire specification of which is expressly incorporated herein by reference.

### FIELD OF THE INVENTION

The present invention relates to an integrated circuit substrate, and more particularly to an integrated circuit substrate provided with a recess for receiving a solder fillet intended for visually verifying a proper interconnection between a package and the substrate attached thereon.

### BACKGROUND OF THE INVENTION

Automatic Visual Inspection (AVI) or Automatic Optical Inspection (AOI) is a process for controlling quality of a manufactured product, such as a semiconductor package, such that failure or defect in the manufactured product can be detected and rectified, so as to reduce the likelihood of refuse device manufacturing. The manufactured product is produced by mounting electronic components to a printed circuit board (PCB) surface via surface mount technology. The surface mount technology enables manufacturing of highly complex electronic circuits into smaller assemblies with good repeatability, and allows automated PCB assembly as well as soldering to be applied.

An integrated circuit substrate can be attached and wire bonded to a PCB through soldering to establish an electrical connection. Leadless packages such as quad flat no-lead (QFN) and dual flat no-lead (DFN) are becoming common for this application as smaller devices are benefiting therefrom. The leadless packages are mounted to a substrate by reflowing a solder material being a liquid alloy to form a fillet between side solderable surfaces and the substrate. Meniscus of the liquid alloy solidifies upon cooling and reflects an illumination useful to manufacturers of electronic devices to visually verify a proper interconnection between the package and the substrate. A good solder-joint generally formed with adequate amount of fillet and shows a slight concave contour with a shiny finishing. If the inspection shows that a proper fillet was not formed thereon, an error is recorded and the manufactured product with faulty connection can be repaired or eliminated.

United States patent application with publication no. US20140357022A1 provides a lead frame assembly for use in fabricating a plurality of QFN packages comprising one or more regions of reduced thickness which extend across an edge of kerf width, and a method of fabricating thereof. The method uses Film Assisted Molding technique, such that a solder fillet formed at an edge structure of the QFN package can easily be seen in a visual inspection process, and results in an increase in reliability of the soldered QFNs. Another United States patent application with publication no. US20110244629A1 discloses a method for fabricating an integrated circuit die in lead frame packages with exposed pad and wettable leads, in which each of the wettable lead is formed by singulating an unplated region on exposed backside surface of a selectively plated lead frame strip to obtain a recess area, and re-plating the recess area to a predetermined thickness.

Accordingly, it would be desirable to provide an integrated circuit substrate with greater manufacturing flexibility as compared to US20140357022A1 and US20110244629A1, in which the integrated circuit substrate comprises one or more electronic conductive layers that are fabricated through building up the components of the integrated circuit substrate from a carrier in a stacked configuration to achieve a thin integrated circuit, fine circuit patterning, and a recess for receiving a solder fillet formed therein. It is also desirable to provide a method of producing such integrated circuit substrate that offers convenient in the fabrication of a substrate for use in a flexible manufacturing system.

### SUMMARY OF THE INVENTION

An object of the invention is to provide an integrated circuit substrate provided with a recess for receiving a solder fillet, in which configuration of the substrate enables formation of a good solder-joint.

Another object of the invention is to provide an integrated circuit substrate provided with a recess for receiving a solder fillet, in which the substrate offers a fine circuit patterning such that it is compatible for use in a flexible manufacturing system.

Further another object of the invention is to provide an integrated circuit substrate provide with a recess for receiving a solder fillet, in which the substrate is fabricated through building up the components from a carrier in a stacked configuration for forming a thin yet rigid substrate.

Still another object of the invention is to provide an integrated circuit substrate provided with a recess for receiving a solder fillet that has minimal or zero material burring in a singulated substrate.

Yet another object of the invention is to provide a method of forming a recess through etching an integrated circuit substrate, in which the method enables precise recess profiling and facilitates controlling of angle during the recess formation.

In a first aspect of the invention there is provided an integrated circuit substrate comprising a conductive trace layer formed by one or more conductive traces that are deposited on a partially or completely removable carrier; a stud conductive trace layer formed by one or more stud traces that are disposed on at least one conductive trace of the conductive trace layer in which each stacked conductive trace and stud trace forms an electronic conductive trace, and all electronic conductive traces positioned at the same level is defined as for forming an electronic conductive layer; a dielectric layer occupying spaces within the stud conductive trace layer and conductive trace layer; and at least one recess formed at the electronic conductive trace of at least one electronic conductive layer, or between two electronic conductive traces of at least one electronic conductive layer; wherein each recess exposes at least one portion of the conductive trace layer, stud conductive trace layer, dielectric layer or any combination thereof.

In this aspect of the invention, the substrate further comprises at least one additional electronic conductive layer deposited on the prior formed electronic conductive layer, wherein the electronic conductive layers are arranged in a stacked configuration.

In this aspect of the invention, the recess is spherically concave.

In this aspect of the invention, the recess formed at the electronic conductive trace exposes at least a portion of both the conductive trace layer and stud conductive trace layer.

In this aspect of the invention, the recess formed between two electronic conductive traces extend to the dielectric layer such that at least a portion of either or both the conductive trace layer and the stud conductive trace layer, and at least a portion of the dielectric layer are exposed.

In this aspect of the invention, the substrate further comprises a finishing layer deposited on either or both the exposed surface of the electronic conductive layer and the recess.

In this aspect of the invention, the conductive trace layer and stud conductive trace layer are made of any one or combination of copper, nickel, and their alloys.

In a second aspect of the invention there is provided a method of producing an integrated circuit substrate comprising the steps of depositing a conductive trace layer formed by one or more conductive traces on a partially or completely removable carrier; depositing a stud conductive trace layer formed by one or more stud traces on at least one conductive trace of the conductive trace layer, in which each stacked conductive trace and stud trace forms an electronic conductive trace, and all electronic conductive traces positioned at the same level is defined as for forming an electronic conductive layer; encapsulating the stud conductive trace layer and the conductive trace layer with a dielectric layer such that the spaces within the stud conductive trace layer and conductive trace layer are occupied by the dielectric layer; and forming at least a recess at the electronic conductive trace of at least one electronic conductive layer, or between two electronic conductive traces of at least one electronic conductive layer, such that each recess exposes at least one portion of the conductive trace layer, stud conductive trace layer, dielectric layer or any combination thereof.

In this aspect of the invention, the method further comprises the step of forming at least one additional electronic conductive layer on the prior formed electronic conductive layer, wherein the electronic conductive layers are arranged in a stacked configuration.

In this aspect of the invention, the conductive trace layer and stud conductive trace layer are deposited through plating or printing processes using electronic conductive material.

In this aspect of the invention, the step of encapsulating the conductive trace layer and stud conductive trace layer is performed through a lamination, printing or molding process using the dielectric layer.

In this aspect of the invention, the method further comprises the step of disposing a masking layer on at least one surface of the carrier before the step of depositing the conductive trace layer.

In this aspect of the invention, the method further comprises the step of disposing a masking layer on top surface of an outermost layer of the substrate before the step of forming the recess.

In this aspect of the invention, the masking layer is provided with an opening for forming the recess in the substrate.

In this aspect of the invention, the method further comprises the step of removing the masking layer and disposing a new masking layer having a larger opening for continuing to enlarge the recess in the substrate.

In this aspect of the invention, the recess is formed through etching the substrate.

In this aspect of the invention, the method further comprises the step of removing the masking layer and depositing a finishing layer on either or both the exposed surface of the electronic conductive layer and the recess.

In this aspect of the invention, the method further comprises the step of singulating the substrate to a sub-substrate, each of which comprising a partial or complete recess.

One skilled in the art will readily appreciate that the present invention is well adapted to carry out the objects and obtain the ends and advantages mentioned, as well as those inherent therein. The embodiment described herein is not intended as limitations on the scope of the invention.

### BRIEF DESCRIPTION OF THE DRAWINGS

For the purpose of facilitating an understanding of the invention, there is illustrated in the accompanying drawing the preferred embodiments from an inspection of which when considered in connection with the following description, the invention, its construction and operation and many of its advantages would be readily understood and appreciated.

FIG. 1 is a diagram showing a carrier of an integrated circuit substrate.

FIG. 2 is a diagram showing the carrier being laminated with a first masking layer on both surfaces of the carrier.

FIG. 3 is a diagram showing formation of a first circuit patterned masking layer from the first masking layer on top surface of the carrier.

FIG. 4 is a diagram showing a first conductive trace layer that is deposited through a plating or printing process into the spaces created on the first patterned mask layer.

FIG. 5 is a diagram showing deposition of a second masking layer on the first circuit patterned masking layer and the conductive trace layer, according to a first preferred embodiment of the invention.

FIG. 6 is a diagram showing formation of a second circuit patterned masking layer from the second masking layer, according to a first preferred embodiment of the invention.

FIG. 7 is a diagram showing a stud conductive layer that is deposited through a plating or printing process into the spaces created from the second circuit patterned masking layer, according to a first preferred embodiment of the invention.

FIG. 8 is a diagram showing the exposed conductive trace layer and stud conductive layer after removing the first circuit patterned masking layer, the second circuit patterned masking layer and the first masking layer deposited at the bottom surface of the carrier, according to a first preferred embodiment of the invention.

FIG. 9 is a diagram showing a dielectric layer encapsulating the exposed conductive trace layer, exposed stud conductive layer and carrier through a laminating, printing or molding process, according to a first preferred embodiment of the invention.

FIG. 10 is a diagram showing a trimmed dielectric layer exposing top surface of the stud conductive trace layer, according to a first preferred embodiment of the invention.

FIG. 11 is a diagram showing deposition of a third masking layer on the trimmed dielectric layer, exposed top surface of the stud conductive trace layer and a bottom carrier masking layer, according to a first preferred embodiment of the invention.

FIG. 12 is a diagram showing formation of a recess exposing at least a portion of the conductive trace layer and stud conductive trace layer, according to a first preferred embodiment of the invention.

FIG. 13 is a diagram showing the recess exposing at least a portion of the conductive trace layer and stud conductive trace layer after removing the third masking layer and the bottom carrier masking layer, according to a first preferred embodiment of the invention.

FIG. 14 is a diagram showing deposition of a fourth masking layer on top surface of the outermost layer of the substrate, and a new masking layer at the bottom surface of the carrier, according to a first preferred embodiment of the invention.

FIG. 15 is a diagram showing partial removal of the carrier.

FIG. 16 is a diagram showing removal of the fourth masking layer and the masking layer at the bottom surface of the carrier, according to a first preferred embodiment of the invention.

FIG. 17 is a diagram showing deposition of a finishing layer on the recess and exposed surface of the electronic conductive layer, according to a first preferred embodiment of the invention.

FIG. 18 is a diagram showing the substrate having a complete recess formed at an electronic conductive layer, such that at least a portion of the conductive trace layer and stud conductive trace layer are exposed, according to a first preferred embodiment of the invention.

FIG. 19 is a series of diagrams showing multi-step etching process for forming the recess in the substrate, through (A) deposition of the third masking layer that is provided with an opening for the etching; (B) removal of the third masking layer; and (C) deposition of a new masking layer having a larger opening for continuing to enlarge the recess.

FIG. 20 is a diagram showing formation of a first circuit patterned masking layer from the first masking layer on top surface of the carrier.

FIG. 21 is a diagram showing a first conductive trace layer that is deposited through a plating or printing process into the spaces created on the first patterned mask layer.

FIG. 22 is a diagram showing the exposed conductive trace layer after removing the first circuit patterned masking layer and the first masking layer deposited at the bottom surface of the carrier, according to a second preferred embodiment of the invention.

FIG. 23 is a diagram showing a first dielectric layer encapsulating the exposed conductive trace layer and the carrier through a laminating, printing or molding process, according to a second preferred embodiment of the invention.

FIG. 24 is a diagram showing a trimmed first dielectric layer exposing the top surface of the conductive trace layer, according to a second preferred embodiment of the invention.

FIG. 25 is a diagram showing deposition of a seed conductive layer on the exposed conductive trace layer and the first dielectric layer, according to a second preferred embodiment of the invention.

FIG. 26 is a diagram showing formation of a second circuit patterned masking layer from a second masking layer, according to a second preferred embodiment of the invention.

FIG. 27 is a diagram showing a stud conductive layer that is deposited through plating or printing process into the gaps created from the second circuit patterned masking layer, according to a second preferred embodiment of the invention.

FIG. 28 is a diagram showing the exposed stud conductive layer and the seed conductive layer after removing the second circuit patterned masking layer and the masking layer deposited at the bottom surface of the carrier, according to a second preferred embodiment of the invention.

FIG. 29 is a diagram showing the exposed stud conductive layer, the first dielectric layer and the conductive trace layer after removing the seed conductive layer, according to a second preferred embodiment of the invention.

FIG. 30 is a diagram showing a second dielectric layer encapsulating the exposed stud conductive layer, the first dielectric layer and the conductive trace layer, according to a second preferred embodiment of the invention.

FIG. 31 is a diagram showing a trimmed second dielectric layer exposing the top surface of the stud conductive trace layer, according to a second preferred embodiment of the invention.

FIG. 32 is a diagram showing deposition of a third masking layer on the trimmed dielectric layer and exposed stud conductive trace layer, and a bottom carrier masking layer, according to a second preferred embodiment of the invention.

FIG. 33 is a diagram showing formation of a recess exposing at least a portion of either or both the conductive trace layer and stud conductive trace layer, and at least a portion of the dielectric layer, according to a second preferred embodiment of the invention.

FIG. 34 is a diagram showing the recess exposing at least a portion of either or both the conductive trace layer and stud conductive trace layer, and at least a portion of the dielectric layer after removing the third masking layer and the bottom carrier masking layer, according to a second preferred embodiment of the invention.

FIG. 35 is a diagram showing deposition a fourth masking layer on top surface of the outermost layer of the substrate, and a masking layer at the bottom surface of the carrier, according to a second preferred embodiment of the invention.

FIG. 36 is a diagram showing partial removal of the carrier.

FIG. 37 is a diagram showing removal of the fourth masking layer and the masking layer at the bottom surface of the carrier, according to a second preferred embodiment of the invention.

FIG. 38 is a diagram showing deposition of a finishing layer on the recess and exposed surface of the electronic conductive layer, according to a second preferred embodiment of the invention.

FIG. 39 is a diagram showing the substrate having a partial recess formed at an electronic conductive layer and extended to the dielectric layer, such that at least a portion of the stud conductive trace layer and at least a portion of the dielectric layer are exposed, according to a second preferred embodiment of the invention.

FIG. 40 is a diagram showing the substrate having a complete recess formed between two electronic conductive layers, such that at least a portion of either or both the conductive trace layer and stud conductive layer are exposed, according to a third preferred embodiment of the invention.

FIG. 41 is a diagram showing the substrate having a partial recess formed between two electronic conductive layers and extended to the dielectric layer, such that at least a portion of the conductive trace layer and stud conductive trace layer, and at least a portion of the dielectric layer are exposed, according to a fourth preferred embodiment of the invention.

FIG. 42 illustrates an exemplary embodiment of a sub-substrate singulated from the substrate, each of which comprising the recess.

### DETAILED DESCRIPTION OF THE INVENTION

The invention will now be described in greater detail, by way of example, with reference to the drawings.

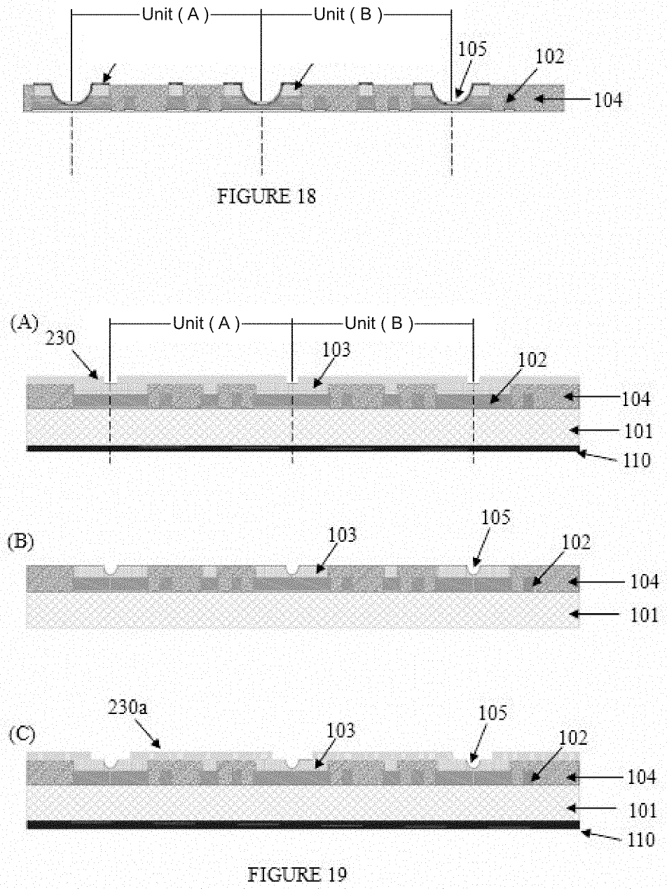

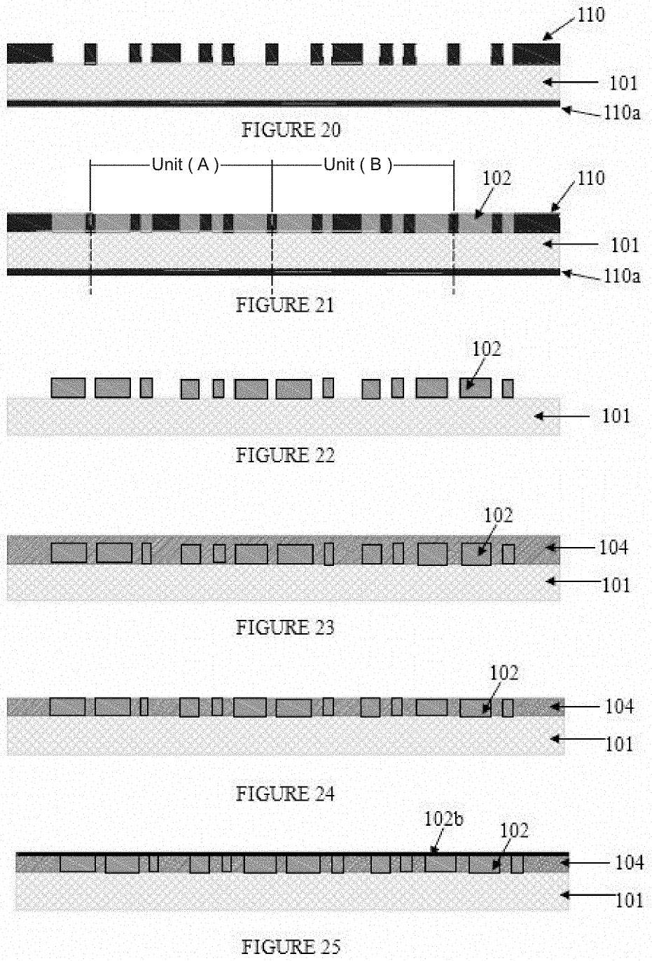

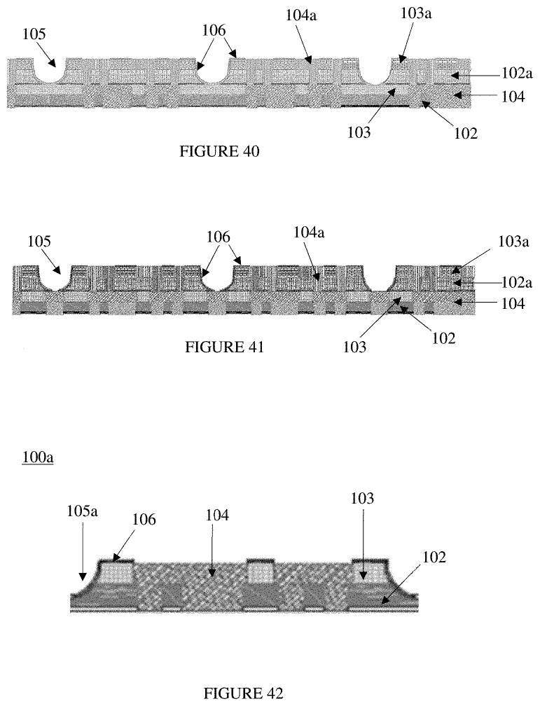

The invention relates to an integrated circuit substrate 100 that is part of an integrated circuit package, in which the substrate 100 is provided with a recess for receiving a solder fillet. The substrate 100 comprises a conductive trace layer 102 formed by one or more conductive traces that are deposited on a partially or completely removable carrier 101, a stud conductive trace layer 103 formed by one or more stud traces that are disposed on at least one conductive trace of the conductive trace layer 102 in which each stacked conductive trace and stud trace forms an electronic conductive trace, and all electronic conductive traces positioned at the same level is defined as an electronic conductive layer; a dielectric layer 104 occupying spaces within the conductive trace layer 102 and stud conductive trace layer 103, and at least one recess 105 formed in the substrate 100 exposing at least a portion of the conductive trace layer 102, stud conductive trace layer 103, dielectric layer 104 or any combination thereof. The substrate 100 further comprises a finishing layer 106 deposited on either or both the exposed surface of the electronic conductive layer and the recess 105. The substrate 100 as illustrated in FIG. 17, FIG. 18, FIG. 38, FIG. 39, FIG. 40 and FIG. 41 are exemplary embodiments of the invention, in which the substrate 100 can be singulated to a sub-substrate 100a, each of which comprising a partial or complete recess 105a.

The electronic conductive layers are arranged in a stacked configuration, in which at least one additional electronic conductive layer is optionally deposited on the prior formed electronic conductive layer. This configuration enables formation of finer circuit patterning and promotes compatibility to a flexible manufacturing system. The electronic conductive layer is formed through a plating or printing process using electronic conductive material in which the conductive trace layer 102 and stud conductive trace layer 103 are respectively formed through plating or printing process, with each stud trace being supported on one or more conductive traces. Preferably, the electronic conductive material that forms the conductive trace layer 102 and stud conductive trace layer 103 are made of any one or combination of copper, nickel, and their alloys. When the stud trace is supported by two conductive traces that are spaced apart, the space therebetween is occupied by the dielectric layer 104 that comprises a non-conductive material. Other spaces between conductive traces and stud traces are also occupied by the dielectric layer 104 through encapsulating the electronic conductive layer by lamination, printing or molding process using the dielectric layer 104.

The recess 105 is formed into a spherically concave shape through etching the substrate 100 at the electronic conductive trace of at least one electronic conductive layer, or between two electronic conductive traces of at least one electronic conductive layer including the two electronic conductive traces and the dielectric layer 104 between the two electronic conductive traces. FIG. 18 and FIG. 40 illustrate one preferred embodiment of the substrate 100, which the substrate 100 possesses a complete recess 105 defined by a recess that exposes at least one portion of the electronic conductive layer that comprises both the conductive trace layer 102 and stud conductive trace layer 103. FIG. 39 and FIG. 41 illustrate another preferred embodiment of the substrate 100, which the substrate 100 possesses a partial recess 105 defined by a recess that forms between two electronic conductive traces of at least one electronic conductive layer and extends to the dielectric layer 104, such that at least a portion of either or both the conductive trace layer 102 and stud conductive trace layer 103, and at least a portion of the dielectric layer 104 are exposed. Particularly, the exposed dielectric layer 104 is the non-conductive material that occupies the space between two conductive traces that support the stud trace. The dielectric layer 104 acts as a stopper to prevent further etching during formation of the recess 105. A singulating process of dividing the substrate 100 to the sub-substrate 100a is performed through a die street that cuts through the recess 105, in which the partial recess 105 produces minimal or zero burring of the electronic conductive material in the sub-substrate 100a, due to lesser or zero contact area to the electronic conductive layer.

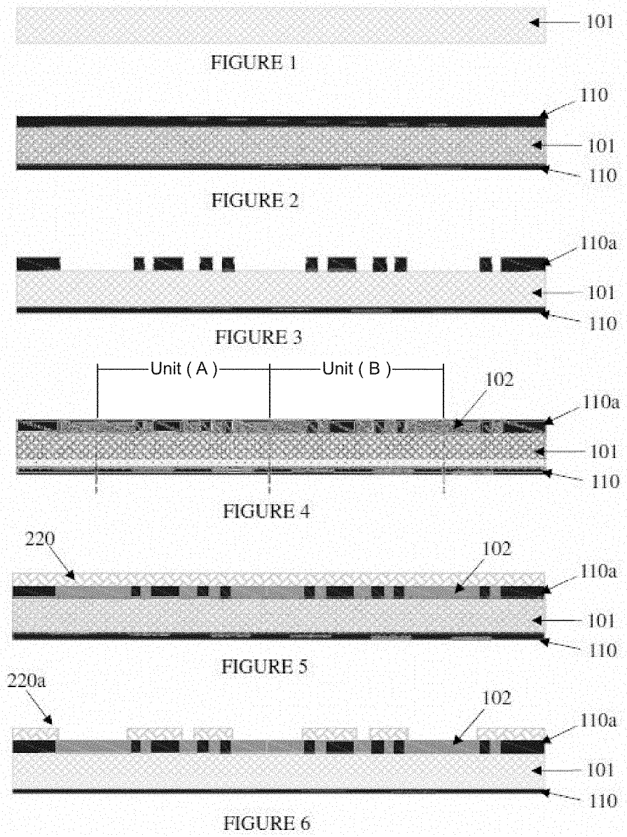

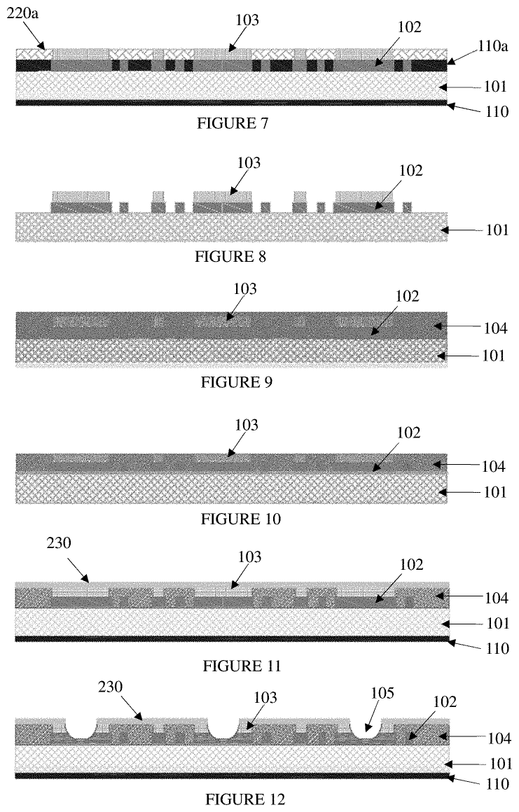

The invention is also characterized by a method of producing the integrated circuit substrate 100 that begins with the provision of a carrier 101 being a charge carrier comprising a steel or carbon steel plated or laminated with pure copper as shown in FIG. 1. With reference to FIG. 2, at least one surface of the carrier 101 is laminated with a first masking layer 110 being a photo-resist material through dry film lamination or coating process. The first masking layer 110 at the bottom surface of the carrier 101 prevents deposition of an electronic conductive material. FIG. 3 shows creation of a first circuit patterned masking layer from the first masking layer 110. Spaces in the first circuit patterned masking layer are deposited with one or more conductive traces to form the conductive trace layer 102 as illustrated in FIG. 4. A second masking layer 220 is deposited on top of the first circuit patterned masking layer 110 and the conductive trace layer 102 for creating a second circuit patterned masking layer with reference to FIG. 5 and FIG. 6. As shown in FIG. 7, one or more stud traces are deposited into the spaces provided in the second circuit patterned masking layer 220 to form the stud conductive trace layer 103. The conductive trace layer 102 and stud conductive trace layer 103 are deposited through a plating or printing process using electronic conductive material, in which the stud traces are disposed on at least one conductive trace of the conductive trace layer 102 for forming an electronic conductive layer which comprises one or more stacked conductive traces and stud traces that each defines an electronic conductive trace.

According to FIG. 8, the masking layers 110 and 220 are removed through dry film stripping process, such that the conductive trace layer 102, stud conductive trace layer 103 and at least a portion of the carrier 101 are exposed. FIG. 9 shows a dielectric layer 104 occupying the space between the conductive trace layer 102 and stud conductive trace layer 103, through a lamination, printing or molding process that encapsulates the conductive trace layer 102 and stud conductive trace layer 103. A trimming, grinding or polishing process is carried out to remove excessive dielectric layer 104 on top surface of the substrate 100 for exposing the top surface of the stud conductive trace layer 103 such that a flattened surface is obtained as illustrated in FIG. 10.

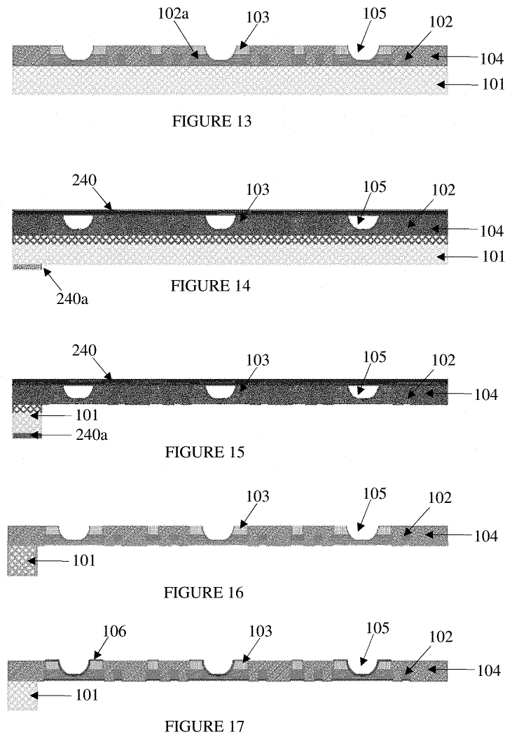

With reference to FIG. 11 and FIG. 12, a third masking layer 230 is disposed on the exposed stud conductive trace layer 103 and the top surface of the dielectric layer 104, in which the third masking layer 230 is provided with an opening for forming a recess 105 in the substrate 100. In one preferred embodiment, the recess 105 is a complete recess that exposes at least a portion of either or both the conductive trace layer 102 and stud conductive trace layer 103. Preferably, the recess 105 is formed through etching the substrate 100. Chemical etching is preferred, but other mechanical cutting or a combination with the chemical etching can also be used for such application. Optionally, the recess 105 is formed through a multi-step etching as illustrated in FIG. 19, in which the third masking layer 230 is removed after forming a recess 105 and a new masking layer 230a having a larger opening is disposed thereon to form a gradually enlarged recess 105 in the substrate 100. This step can be repeated, each time with an additional masking layer with larger opening disposed on a previously etched masking layer. The multi-step etching enables precise recess profiling and facilitates angle controlling during formation of the recess 105. Upon complete forming of the recess 105, the masking layers 110 and 230 are removed from the substrate 100 as shown in FIG. 13.

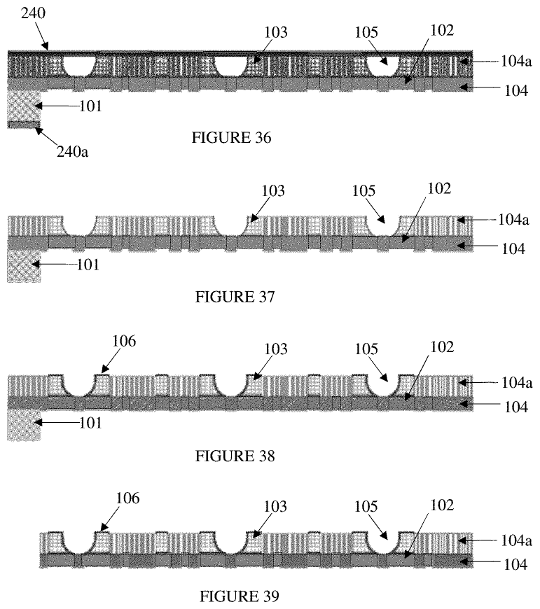

The substrate 100 is disposed with a fourth masking layer 240 for protecting the recess 105 and the finished surface, and a masking layer 240a at the bottom surface of the carrier 101. The masking layer 240a can be formed into a carrier pattern as illustrated in FIG. 14 and FIG. 36, for partially or completely removal of the carrier 101 through any one or combination of techniques including chemical release, thermal release, laser release, mechanical release or etching process. The partially removed carrier 101 provides a support to the substrate 100 until a singulating step is performed to divide the substrate 100 into at least two sub-substrates 100a through a die street as indicated by a dotted line as shown in FIG. 18. Prior to the singulation step, either or both the exposed surface of the electronic conductive layer and the recess 105 is deposited with a finishing layer 106.

While FIG. 13 shows an embodiment of the substrate 100 with one electronic conductive layer and carrier and FIG. 18 depicts an embodiment of the substrate 100 with one electronic layer without a carrier 101, FIG. 40 illustrates another preferred embodiment of the substrate 100 with more than one electronic layers that are arranged in a stacked configuration, in which at least one additional electronic conductive layer is formed on the prior formed electronic conductive layer before forming the recess 105 in the substrate 100. Particularly, the recess 105 can extend to more than one electronic conductive layer. In FIG. 40, the recess 105 extends to two electronic conductive layers. A complete recess 105 is formed at the electronic conductive traces of two electronic layers, such that at least a portion of either or both the conductive trace layer 102 and stud conductive layer 103 are exposed. Although the exemplary substrate 100 with two stacked electronic conductive layers shown in FIG. 40 has its carrier 101 removed, it should be noted that removal of the carrier 101 is optional.

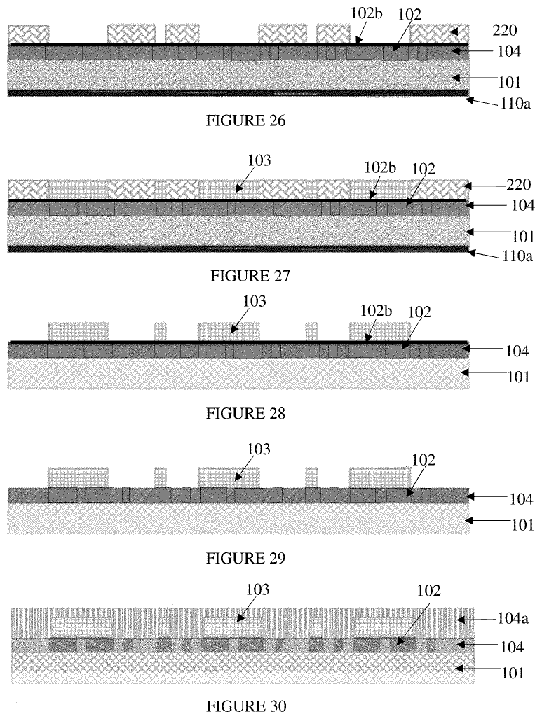

The invention also describes a method of producing the substrate 100 having the recess 105 being a partial recess formed between the two electronic conductive traces of at least one electronic conductive layer and extends to the dielectric layer 104, such that at least a portion of either or both the conductive trace layer 102 and stud conductive trace layer 103, and at least a portion of the dielectric layer 104 are exposed. With reference to FIG. 22 to FIG. 24, a first dielectric layer 104 encapsulates the conductive trace layer 102 through lamination or printing prior to a trimming process to flatten and expose the conductive trace layer 102. According to FIG. 25, a seed conductive layer 102b is deposited thereon for electrolytic plating to be performed. Particularly, a second circuit patterned masking layer 220 is deposited on the seed conductive layer 102b, in which the spaces provided by the second circuit patterned masking layer 220 to be deposited with the stud traces are located on top of two conductive traces that has a space filled with the dielectric layer 104 as shown in FIG. 26 to FIG. 28. Subsequently, the seed conductive layer 102b is removed through micro-etching to arrive to the substrate 100 as shown in FIG. 29.

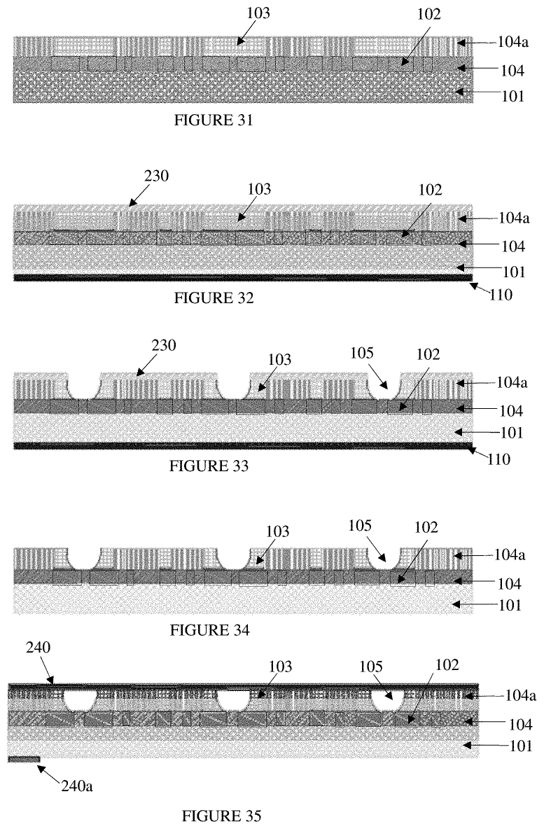

According to FIG. 30 and FIG. 31, a second dielectric layer 104a encapsulating exposed surface of the conductive trace layer 102 and stud conductive trace layer 103 through lamination, printing or molding is trimmed to expose the top surface of the stud conductive trace layer 103. Subsequently, a masking layer 230 having an opening for forming the recess 105 is disposed prior to forming the recess 105 with reference to FIG. 32 and FIG. 33. This configuration enables the first dielectric layer 104 to act as a stopper during the etching process, and enables the recess 105 to expose at least a portion of either or both the conductive trace layer 102 and stud conductive trace layer 103, and at least a portion of the dielectric layer 104. The finishing layer 106 is deposited on either or both the exposed surface of the electronic conductive layer and the recess 105. Examples of such embodiment are illustrated in FIG. 39 and FIG. 41.

While FIG. 34 shows an embodiment of the substrate 100 with one electronic conductive layer and carrier 101 and FIG. 18 depicts an embodiment of the substrate 100 with one electronic layer without a carrier 101, FIG. 41 illustrates an embodiment of the substrate 100 with more than one stacked electronic layers without a carrier 101. Although not shown in the accompanying drawings, the carrier 101 of a substrate 100 with more than one stacked electronic layers can be retained. In the embodiment of the substrate 100 having more than one stacked electronic conductive layers, the partial recess is formed between two electronic conductive traces of one or more electronic conductive layers, and extends from the outermost electronic conductive layers to more than one inner electronic conductive layers. In the substrate 100 shown in FIG. 41, the recess 105 is a partial recess 105 that extends to two electronic conductive layers and exposes at least a portion of either or both the conductive trace layer 102 and stud conductive trace layer 103, and at least a portion of the dielectric layer 104.

The method further includes the step of singulating the substrate 100 to a sub-substrate 100a as illustrated in FIG. 42, through a die street that cuts through the recess 105. Each of the sub-substrate 100a comprising a partial or complete recess 105a is ready for use in a next level of assembly.

The present disclosure includes as contained in the appended claims, as well as that of the foregoing description. Although this invention has been described in its preferred form with a degree of particularly, it is understood that the present disclosure of the preferred form has been made only by way of example and that numerous changes in the details of construction and the combination and arrangements of parts may be resorted to without departing from the scope of the invention.

What is claimed is:

1. An integrated circuit substrate, comprising:
a conductive trace layer formed by one or more conductive traces that are deposited on a partially or completely removable carrier;
a stud conductive trace layer formed by one or more stud traces that are disposed on at least one conductive trace of the conductive trace layer, in which each stacked conductive trace and stud trace forms an electronic conductive trace, and all electronic conductive traces positioned at the same level is defined as an electronic conductive layer;
a dielectric layer occupying spaces within the stud conductive trace layer and conductive trace layer; and
at least one recess formed at the electronic conductive trace or between two electronic conductive traces;
wherein each recess exposes at least a portion of the conductive trace layer, stud conductive trace layer, dielectric layer or any combination thereof.

2. The substrate according to claim 1, further comprising at least one additional electronic conductive layer deposited on the prior formed electronic conductive layer, wherein the electronic conductive layers are arranged in a stacked configuration.

3. The substrate according to claim 1, wherein the recess is spherically concave.

4. The substrate according to claim 1, wherein the recess formed at the electronic conductive trace of at least one electronic conductive layer exposes at least a portion of both the conductive trace layer and stud conductive trace layer.

5. The substrate according to claim 1, wherein the recess formed between two electronic conductive traces of at least one electronic conductive layer extend to the dielectric layer such that at least a portion of either or both the conductive trace layer and the stud conductive trace layer, and at least a portion of the dielectric layer are exposed.

6. The substrate according to claim 1, further comprising a finishing layer deposited on either or both an exposed surface of the electronic conductive layer and the recess.

7. The substrate according to claim 1, wherein the conductive trace layer and stud conductive trace layer are made of any one or combination of copper, nickel, and their alloys.

8. A method of producing an integrated circuit substrate, comprising the steps of:
depositing a conductive trace layer formed by one or more conductive traces on a partially or completely removable carrier;
depositing a stud conductive trace layer formed by one or more stud traces on at least one conductive trace of the conductive trace layer in which each stacked conductive trace and stud trace forms an electronic conductive trace, and all electronic conductive traces positioned at the same level is defined as an electronic conductive layer;
encapsulating the stud conductive trace layer and the conductive trace layer with a dielectric layer such that the spaces within the stud conductive trace layer and conductive trace layer are occupied by the dielectric layer; and
forming at least one recess in the substrate at the electronic conductive trace of at least one electronic conductive layer, or between two electronic conductive traces of at least one electronic conductive layer, such that each recess exposes at least one portion of the conductive trace layer, stud conductive trace layer, dielectric layer or any combination thereof.

9. The method according to claim 8, further comprising the step of forming at least one additional electronic conductive layer on the prior formed electronic conductive layer, wherein the electronic conductive layers are arranged in a stacked configuration.

10. The method according to claim 8, wherein the conductive trace layer and stud conductive trace layer are deposited through a plating process or a printing process using electronic conductive material.

11. The method according to claim 8, wherein the step of encapsulating the conductive trace layer and stud conductive trace layer is performed through a lamination, printing or molding process using the dielectric layer.

12. The method according to claim 8, further comprising the step of disposing a masking layer on at least one surface of the carrier before the step of depositing the conductive trace layer.

13. The method according to claim 8, further comprising the step of disposing a masking layer on a surface of an outermost most layer of the substrate before the step of forming the recess.

14. The method according to claim 13, wherein the masking layer is provided with an opening for forming the recess in the substrate.

15. The method according to claim 14, further comprising the step of removing the masking layer and disposing a new masking layer having a larger opening for continuing to enlarge the recess in the substrate.

16. The method according to claim 15, wherein the recess is formed through etching the substrate.

17. The method according to claim 16, further comprising the step of removing the masking layer and depositing a finishing layer on either or both an exposed surface of the electronic conductive layer and the recess.

18. The method according to claim 17, further comprising the step of singulating the substrate to a sub-substrate, each of which comprising a partial or complete recess.
